(19) United States
(12) Patent Application Publication
(10) Pub. No.: US 2025/0228143 A1
(43) Pub. Date: Jul. 10, 2025

(54) SEMICONDUCTOR DEVICE AND METHOD OF FORMING THE SAME

(71) Applicant: Taiwan Semiconductor Manufacturing Company, Ltd., Hsinchu (TW)

(72) Inventors: Ching-Ju Yang, Hsinchu (TW); Huan-Chieh Chen, Taichung (TW); Yao-Wen Chang, Taipei (TW)

(73) Assignee: Taiwan Semiconductor Manufacturing Company, Ltd., Hsinchu (TW)

(21) Appl. No.: 18/408,584

(22) Filed: Jan. 10, 2024

(51) Int. Cl. H10N 70/20; H10N 70/00

(52) U.S. Cl. CPC H10N 70/231; H10N 70/063; H10N 70/823; H10N 70/8413; H10N 70/8828

(57) ABSTRACT

A semiconductor device and a method of forming the same are provided. The semiconductor device includes a phase change material element over a substrate, a first conductive structure, a second conductive structure, a heating structure and a first capping layer. The phase change material element includes a body portion and a surface portion on a top surface of the body portion. A nitrogen concentration of the surface portion is larger than a nitrogen concentration of the body portion. The first conductive structure is physically and electrically connected to the phase change material element. The second conductive structure is physically and electrically connected to the phase change material element. The first conductive structure and the second conductive structure are laterally spaced apart. The heating structure is configured to heat the phase change material structure. The first capping layer is disposed on the surface of the phase change material element.

### BACKGROUND

The semiconductor integrated circuit (IC) industry has experienced exponential growth and with the continuous development of communication technology, the increasing market for radio frequency (RF) devices has resulted in a significant increase in the demand for RF switch devices. For example, a smartphone may incorporate ten or more RF switch devices to switch a received signal to appropriate bands.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1A is a schematic cross-sectional view of a semiconductor device according to some embodiments of the present disclosure.

FIG. 1B is a schematic top view of a semiconductor device according to some embodiments of the present disclosure.

FIG. 2A is an X-ray photoelectron spectroscopy (XPS) analysis for an example stacking structure of the PCM element and the first capping layer according to some embodiments of the present disclosure.

FIG. 2B is an Energy Dispersive X-ray spectroscopy (EDX) line scan profile for an example stacking structure of the PCM element and the first capping layer according to some embodiments of the present disclosure.

FIGS. 3A to 3O are schematic cross-sectional views illustrating structures formed at various stages of a method of forming a semiconductor device according to some embodiments of the present disclosure.

FIG. 4 is a flowchart illustrating operations of a method of forming the semiconductor device, according to some embodiments of the present disclosure.

FIG. 5 is an X-ray diffraction (XRD) analysis result for an example of the surface of the phase change material layer before and after the nitridation treatment according to some embodiments of the present disclosure.

FIG. 6 is a schematic cross-sectional view of a semiconductor device according to some embodiments of the present disclosure.

FIGS. 7A to 7E are schematic cross-sectional views illustrating structures formed at various stages of a method of forming a semiconductor device according to some embodiments of the present disclosure.

FIG. 8 is a flowchart illustrating operations of a method of forming the semiconductor device, according to some embodiments of the present disclosure.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

As used herein, “around”, “about”, “approximately”, or “substantially” shall generally mean within 20 percent, or within 10 percent, or within 5 percent of a given value or range. Numerical quantities given herein are approximate, meaning that the term “around”, “about”, “approximately”, or “substantially” can be inferred if not expressly stated.

According to embodiments of the present disclosure, a semiconductor device including phase change material (PCM) switches is described. PCM switches may be used to provide a switching function for various semiconductor devices such as radio-frequency semiconductor devices, varactors (e.g., variable capacitance capacitors), inductors, or other semiconductor devices. As used herein, a “phase change material” refers to a material having at least two distinct phases providing different resistivity. The distinct phases may include an amorphous state having relatively high resistivity and a crystalline state having relatively low resistivity (i.e., a lower resistivity than in the amorphous state). For a switch used in radio-frequency (RF) applications, relevant factors for evaluating switch performance may include insertion loss, isolation, and power handling. In general, low insertion loss and high isolation are desirable characteristics for RF switches. For PCM switches, insertion loss may be related to the resistivity R_{ON} across the phase change material when the switch is in the “On” state, while high isolation is inversely related to the capacitance C_{OFF} of the switch while in the “Off” state. A figure of merit (FOM) that may be used to characterize performance of a PCM switch may be chosen to have a value that is inversely proportional to the product R_{ON}*C_{OFF}. For example, one FOM that may be used to characterize switch performance may be taken to be ˜1/(2πR_{ON}*C_{OFF}). This FOM has frequency units and may be related to a maximum frequency at which the PCM material may be switched from an “On” state to an “Off” state. In general, increasing the value the FOM may be associated with improved switch performance. Thus, switch performance may be improved by reducing the R_{ON} characteristics, reducing the C_{OFF} characteristics, or both, in a PCM switch.

During fabrication of the PCM switch, a surface of the phase change material layer may be oxidized and therefore oxides may be formed on the surface of the phase change material layer resulting in an increase in the resistivity R_{ON} across the phase change material when the switch is in the “On” state, and thereby reducing the switch performance.

Various disclosed embodiments include PCM switches that may provide reduced resistivity R_{ON} of PCM switch in the “ON” state. In some embodiments, a surface treatment is performed on a phase change material layer, so that oxides formed on the surface of the phase change material layer may be reduced and thereby reducing the resistivity R_{ON} of the PCM switch in the “ON” state and improving the switch performance. In other embodiments, a phase change material layer and a capping layer on the phase change material layer are formed in-situ, so that an oxide may not formed on the surface of the phase change material layer and thereby reducing the resistivity R_{ON} of the PCM switch in the “ON” state and improving the switch performance.

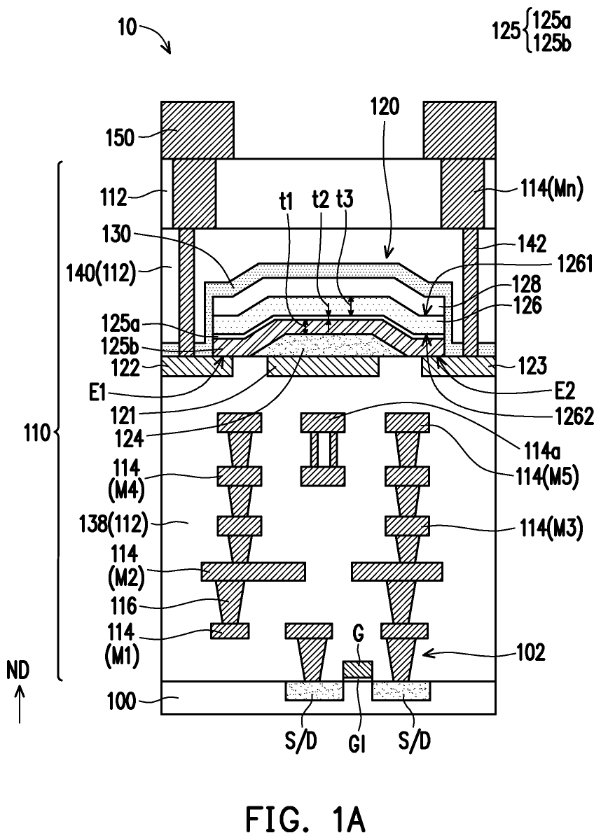

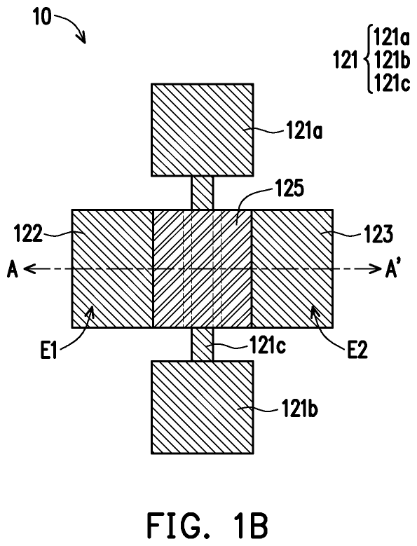

FIG. 1A is a schematic cross-sectional view of a semiconductor device 10 according to some embodiments of the present disclosure. FIG. 1B is a schematic top view of a semiconductor device according to some embodiments of the present disclosure. FIG. 1A may be the cross-sectional view cutting along line A-A′ in FIG. 1B. For clarity, FIG. 1B shows only the PCM element 125, the heating structure 121, the first conductive structure 122 and the second conductive structure 123, and omits other components.

Referring to FIG. 1A, a semiconductor device 10 is described. The semiconductor device 10 includes an interconnect structure 110 and a phase change material (PCM) switch 120. The interconnect structure 110 is over a substrate 100. In some embodiments, the substrate 100 may be a silicon (Si) substrate. In some other embodiments, the substrate 100 may include other semiconductors such as germanium (Ge), silicon germanium (SiGe), or a III-V semiconductor material. Example III-V semiconductor materials may include gallium arsenide (GaAs), indium phosphide (InP), gallium phosphide (GaP), gallium nitride (GaN), gallium arsenide phosphide (GaAsP), aluminum indium arsenide (AlInAs), aluminum gallium arsenide (AlGaAs), gallium indium phosphide (GaInP), and indium gallium arsenide (InGaAs). The substrate 100 may also include a buried insulating layer, such as a buried silicon oxide layer, to have a silicon-on-insulator (SOI) structure.

Referring to FIG. 1A, in some embodiments, one or more active devices 102, such as metal-oxide-semiconductor field-effect transistors (MOSFETs), complementary metal-oxide-semiconductor (CMOS) transistors, fin field-effect transistors (FinFETs), gate-all-around field-effect transistors (GAA FETs) and etc., may be disposed on/over the substrate 100. Each of the active devices 102 includes a pair of source/drain regions S/D in the substrate 100, as well as a gate electrode G and a gate dielectric layer GI stacked between the source/drain regions S/D. The gate dielectric layer GI is located between the gate electrode G and the substrate 100.

Referring to FIG. 1A, in some embodiments, the interconnect structure 110 may include a dielectric structure 112, a plurality of conductive layers 114, and a plurality of vias 116. In some embodiments, the dielectric structure 112 may include one or more stacked dielectric layers. The plurality of conductive layers 114 are disposed in the dielectric structure 112 and includes a first conductive layer M1, a second conductive layer M2, a third conductive layer M3, a fourth conductive layer M4, the fifth conductive layer M5, and a nth conductive layer Mn. The plurality of vias 116 are disposed in the dielectric structure 112, and vertically connected between adjacent conductive layers 114. In some embodiments, the dielectric structure 112 may include one or more stacked dielectric layers, which may respectively include a silicon oxide (e.g., SiO₂), a low-k dielectric (e.g., a dielectric material with a dielectric constant less than about 3.9), or the like. The conductive layers 114 and the vias 116 may be or include, for example, copper (Cu), gold (Au), silver (Ag), tungsten (W), or other suitable conductive material.

Referring to FIG. 1A, in some embodiments, the semiconductor device 10 further includes a plurality of contact pads 150 disposed on the interconnect structure 110. The contact pads 150 may electrically connected to the conductive layers of the interconnect structure 110. In some embodiments, the contact pads 150 may be or include, for example, copper (Cu), gold (Au), silver (Ag), tungsten (W), aluminum (Al), Titanium (Ti), an alloy or a combination thereof, or other suitable conductive material.

Referring to FIG. 1A, the PCM switch 120 is disposed in the interconnect structure 110. In FIG. 1A, the PCM switch 120 is disposed between the fifth conductive layer M5 and the nth conductive layer Mn, but it is not limited. The PCM switch 120 may be disposed between any two adjacent conductive layers 114 of the interconnect structure 110. In some embodiments, the PCM switch 120 is sandwiched between interlayer dielectric (ILD) layers 138 and 140. In some embodiments, the ILD layer 138 or 140 includes an silicon oxide (e.g., SiO₂), a low-k dielectric, or the like. The ILD layers 138 and 140 may be one of the dielectric layers in the dielectric structure 112. This shows that the PCM switch 120 may be disposed in one or more dielectric layers of the dielectric structure 112.

Referring to FIGS. 1A and 1B, the PCM switch 120 includes a heating structure 121, a first conductive structure 122, a second conductive structure 123, and a phase change material (PCM) element 125. The heating structure 121 is disposed on the interlayer The PCM element 125 is disposed over the heating structure 121. The first conductive structure 122 is physically and electrically connected to a first end E1 of the PCM element 125. The second conductive structure 123 is physically and electrically connected to a second end E2 of the PCM element 125 opposite to the first end E1 of the PCM element 125.

Referring to FIGS. 1A and 1B, in the PCM switch 120, the heating structure 121 is configured to heat the PCM element 125 to switch the phase of the PCM element 125, such that the PCM element 125 may be selectively switched between an amorphous phase and a crystalline phase. For example, an amorphous phase of the PCM element 125 may be switched to a crystalline phase of the PCM element 125 by slow heating the PCM element 125 to a crystalline temperature of the PCM element 125 and slow cooling the PCM element 125. A crystalline phase of the PCM element 125 may be switched to an amorphous phase of the PCM element 125 by fast heating the PCM element 125 to a melting point of the PCM element 125 and fast cooling the PCM element 125. In some embodiments, a resistive state (e.g., high-resistive state or low-resistive state) of the PCM element 125 is based on the phase of the PCM element 125. For example, the PCM element 125 may be in the high-resistive state when the PCM element 125 has an amorphous phase, and the PCM element 125 may be in the low-resistive state when the PCM element 125 has a crystalline phase. That is to say, the PCM element 125 may be selectively switched between a high-resistive state (corresponding to “OFF” state of the PCM switch) and a low-resistive state (corresponding to “ON” state of the PCM switch) by heating the PCM element 125.

Referring to FIGS. 1A and 1B, in some embodiments, the heating structure 121 includes a first heater pad 121a, a second heater pad 121b and a heating element 121c. The heating element 121c is connected between the first heater pad 121 and the second heater pad 121b and is overlapped with the PCM element 125 in a normal direction ND of the substrate 100. The first heater pad 121a and the second heater pad 121b may be electrically connected to the corresponding active device 102 through the conductive layers 114 of the interconnect structure 110. An application of voltage difference between the first heater pad 121a and the second heater pad 121b may generate an electrical current that may flow from the first heater pad 121a, through the heating element 121c, and to the second heater pad 121b, or from the second heater pad 121b, through the heating element 121c, and to the first heater pad 121a. The first heater pad 121a and the second heater pad 121b may be configured to have a considerably larger width than that of the heating element 121c, so that for a given applied voltage difference, the current density may be considerably larger in the heating element 121c relative to that in either of the first heater pad 121a and the second heater pad 121b. As such, heat may be preferentially generated by the heating element 121c and may be delivered to the PCM element 125. In some embodiments, a heat dissipation structure 114a composed of a portion of the conductive layers 114 may be located directly below the heating element 121c to improve removal of heat generated in the PCM element 125 after a switching event. In some embodiment, the heat dissipation structure 114a may be electrical isolated from other conductive layers 114 in the interconnect structure 110.

In some embodiments, the heating structure 121 may be heat resistant and have low resistivity. For example, a material of the heating structure 121 may be a metal (e.g., tungsten (W), iridium (Ir), ruthenium (Ru), platinum (Pt), gold (Au), or the like), a metal nitride (e.g., TiN), some other conductive material, or a combination of the foregoing (e.g., a combination of tungsten (W) and TiN). In some embodiments, the heating structure 121 has a melting temperature greater than or equal to about 1000° C. In some embodiments, the heating structure 121 has a resistivity that is less than or equal to about 10.4×10⁻⁸ ohm-meter. In some embodiments, each of the first heater pad 121a, the second heater pad 121b, and the heating element 121c, may be formed of the same conducting material. Alternatively, two or more different electrically conducting materials may be used for the first heater pad 121a, the second heater pad 121b, and the heating element 121c.

Referring to FIGS. 1A and 1B, in some embodiments, the heating structure 121 is disposed below the phase change material structure 125, which is not limited, as long as the heating structure 121 is capable of heating the PCM layer 125 to enable the phase change. In other embodiments, the heating structure 121 may disposed above the PCM element 125. In some embodiments, the heating structure 121 is overlapped with a portion of the PCM element 125 in a normal direction ND of the substrate 100.

Referring to FIGS. 1A and 1B, in some embodiments, the first conductive structure 122 and the second conductive structure 123 are laterally spaced apart and connected to the PCM element 125 to form a signal transmission path way. In some embodiments, the PCM element 125 may cross over the heating structure 121 to connect between the first conductive structure 122 and the second conductive structure 123. For example, the first conductive structure 122 and the second conductive structure 123 may be disposed below and in direct contact with the PCM element 125, and the heating structure 121 may be disposed between the first conductive structure 122 and the second conductive structure 123. The dielectric structure 112 may separate the heating structure 121, the first conductive structure 122 and the second conductive structure 123 to electrically isolate the heating structure 121 from the first conductive structure 122 and the second conductive structure 123. In some embodiments, the heating structure 121, the first conductive structure 122 and the second conductive structure 123 may be at the same conductive layer. In this case, a material of the first conductive structure 122 and a material of the second conductive structure 123 may be the same as the material of the heating structure 121, but it is not limited thereto. The material of the first conductive structure 122 and the material of the second conductive structure 123 may be different. In other embodiments, the first conductive structure 122 and the second conductive structure 123 may be disposed on the PCM element 125 and the heating structure 121 is disposed under the PCM element 125. That is, the heating structure 121 as well as the first conductive structure 122 and the second conductive structure 123 may be located on different sides of the PCM element 125.

In some embodiments, the first conductive structure 122 and the second conductive structure 123 may respectively be or include, for example, a metal (e.g., tungsten (W), copper (Cu), gold (Au), silver (Ag), or the like), a metal nitride (e.g., titanium nitride (TiN), tantalum nitride (TaN), or the like), some other conductive material, or a combination of the foregoing. In further embodiments, a material of the first conductive structure 122 may be the same as a material of the second conductive structure 123.

Referring to FIG. 1A, in some embodiments, the PCM switch 120 further includes a first capping layer 126 disposed on the PCM element 125 and a second capping layer 128 disposed on the first capping layer 126. In some embodiments, a material of the first capping layer 126 includes silicon nitride, silicon carbide, silicon carbonitride, or other suitable insulating materials. In some embodiments, the second capping layer 128 may be or include, for example, a silicon oxide (e.g., SiO₂), a silicon nitride (e.g., SiN), a silicon oxynitride (e.g., SiON), some other insulating material, or a combination of the foregoing. In some embodiments, a material of the second capping layer 128 is different from the first capping layer 126. For example, the first capping layer 126 may be silicon nitride and the second capping layer 128 may be silicon oxide.

Referring to FIG. 1A, in some embodiments, the PCM switch 120 further includes a thermal barrier layer 124 between the heating structure 121 and the PCM element 125. In some embodiments, the thermal barrier layer 124 may be or include, for example, a silicon nitride (SiN), a silicon carbide (SiC), a silicon carbonitride (SiCN), a metal nitride (e.g., aluminum nitride (AlN)), carbon (C), some other thermal barrier material, or a combination of the foregoing.

Referring to FIG. 1A, in some embodiments, the semiconductor device 10 further includes a passivation layer 130 disposed on the PCM switch 120 to protect the PCM switch 120 from being damaged. The passivation layer 130 may cover a top surface and sidewalls of the second capping layer 128, sidewalls of the first capping layer 126, sidewalls of the PCM element 125, a top surface of the first conductive structure 122 and a top surface of the second conductive structure 123. The passivation layer 130 may be covered by the ILD layer 140. In some embodiments, the second capping layer 128 is disposed between the first capping layer 126 and the passivation layer 130. In some embodiments, a material of the passivation layer 130 includes silicon nitride, silicon carbide, silicon carbonitride, or other suitable insulating materials. In some embodiments, the material of the passivation layer 130 is the same as that of the first capping layer 126, but it is not limited thereto. In other embodiments, the material of the passivation layer 130 may be different from that of the first capping layer 126.

Referring to FIG. 1A, in some embodiments, the PCM switch 120 may be a radio frequency (RF) switch. The first conductive structure 122 and the second conductive structure 123 may electrically connected to the contact pads 150, and thus an RF signal may be transmitted to or received from an external device (such as antenna and etc.). In some embodiments, the contact pad 150 may connected to the first conductive structure 122 or the second conductive structure 123 through a conductive layer 114 and a via 142. The via 142 may penetrate through the ILD layer 140 and the passivation layer 130 to connect between the first conductive structure 122 or the second conductive structure 123 and the conductive layer 114. In FIG. 1A, one conductive layer is disposed over the PCM switch 120, but it is not limited thereto. One or more conductive layers may be disposed above and/or under the PCM switch 120 depending on the design requirement.

Referring to FIG. 1A, the PCM element 125 includes a germanium-containing chalcogenide. In some embodiments, a material of the PCM element 125 may include germanium telluride (GeTe), germanium antimony telluride (GeSbTe), other suitable materials capable of changing resistive states by changing phases or a combination of the foregoing. In some embodiments, the PCM element 125 may be doped or undoped, which is not limited.

Referring to FIG. 1A, in some embodiments, the PCM element 125 is surface-treated and thus the PCM element 125 may be considered to have two portions (for example, a surface portion 125a and a body portion 125b) including different chemical compositions. In some embodiments, the PCM element 125 is surface-treated by a nitridation treatment to remove an oxide layer formed on the surface of the PCM element 125, and thus the surface portion 125a and the body portion 125b includes germanium-containing chalcogenide, and the surface portion 125a may further include nitrogen (N). Since the body portion 125b may not be surface-treated, the body portion 125b mainly includes germanium-containing chalcogenide and may include little or no nitrogen. Therefore, a nitrogen concentration of the surface portion 125a is larger than a nitrogen concentration of the body portion 125b. In some embodiments, the surface portion 125a includes germanium-containing chalcogenide, nitrogen and oxygen. In further embodiments, an amount of nitrogen in the surface portion 125a is larger than an amount of oxygen in the surface portion 125a.

Referring to FIG. 1A, the surface portion 125a is thinner than the body portion 125b. In some embodiments, a ratio of a thickness t2 of the surface portion 125a to a thickness t1 of the body portion 125b is between 0.005 to 0.1. In some embodiments, a thickness t1 of the body portion 125b may be between about 500 angstroms and about 2000 angstroms, which is not limited. In some embodiments, the surface portion 125a may have a thickness t2 between about 10 angstroms and about 50 angstroms.

Referring to FIG. 1A, in some embodiments, the surface portion 125a is disposed between the body portion 125b and the first capping layer 126. In some embodiments, a nitrogen concentration of the surface portion 125a is larger than a nitrogen concentration of the first capping layer 126. In some embodiments, a ratio of the nitrogen concentration of the surface portion 125a to the nitrogen concentration of the first capping layer 126 is larger than 1.1. The term “concentration” used herein or elsewhere in the specification refers to “atomic concentration. The surface portion 125a is thinner than the first capping layer 126. In some embodiments, a ratio of the thickness t2 of the surface portion 125a to a thickness t3 of the first capping layer 126 is between 0.002 to 0.5. In some embodiments, a thickness t3 of the first capping layer 126 may be between about 100 angstroms and about 5000 angstroms, which is not limited.

Referring to FIG. 1A, from other points of view, the surface portion 125a may be regarded as a nitrogen-containing layer 125a and the body portion 125b may be regarded as a PCM structure 125b. The nitrogen-containing layer 125a may be formed by a surface treatment to the PCM element 125, so the nitrogen-containing layer 125a may be bonded to the PCM structure 125b by a chemical bond. In further embodiments, the nitrogen-containing layer 125a may be bonded to the PCM structure 125b by Ge—N bonds, Ge—Te bonds or the like.

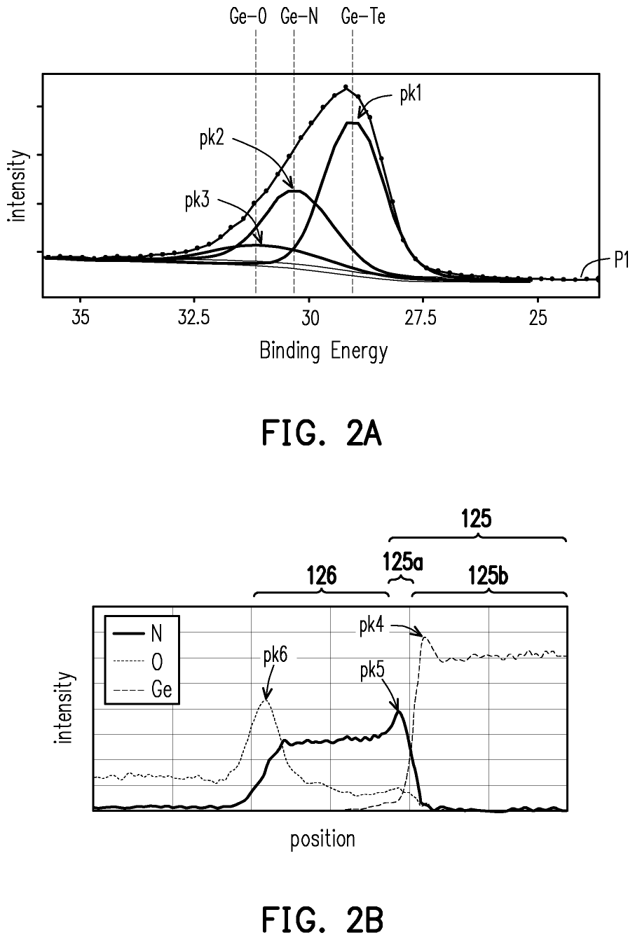

FIG. 2A is an X-ray photoelectron spectroscopy (XPS) analysis for an example stacking structure of the PCM element 125 and the first capping layer 126 according to some embodiments of the present disclosure. FIG. 2B is an Energy Dispersive X-ray spectroscopy (EDX) line scan profile for an example stacking structure of the PCM element 125 and the first capping layer 126 according to some embodiments of the present disclosure. The example stacking structure includes a PCM element 125 containing germanium telluride (GeTe), and a first capping layer 126 containing silicon nitride (SiN), which are sequentially stacked. The PCM element 125 includes a surface portion 125a and a body portion 125b, where the surface portion 125a of the PCM element 125 was nitrided, but the body portion 125b of the PCM element 125 was not nitrided. The surface portion 125a of the PCM element 125 was analyzed by XPS around the binding states of Ge3d and the result is shown in FIG. 2A. The EDX line scan was performed to the example stacking structure to analyze the elementary distribution of nitrogen (N), oxygen (O) and germanium (Ge) in the example stacking structure and the result is shown in FIG. 2B.

In FIG. 2A, the overall profile P1 of XPS spectra can be decomposed into three peaks pk1, pk2 and pk3. The peak pk1 corresponds to Ge, the peak pk2 corresponds to Ge—N bonds and the peak pk3 corresponds to Ge—O bonds. This shows that the surface portion 125a of the PCM element 125 may include germanium, nitrogen and a small amount of oxygen, and the content of Ge—N bonds is larger than the content of Ge—O bonds in the surface portion 125a.

Besides, according to the EDX line scan analysis shown in FIG. 2B, it also shows that the surface portion 125a of the PCM element 125 may include germanium, nitrogen and a small amount of oxygen In detail, the Ge-curve maintains at a high intensity in the body portion 125b since the body portion 125b includes GeTe. Ge-curve has a peak pk4 at the body portion 125b near the interface between the surface portion 125a and the body portion 125b. The intensity of Ge gradually decreases in the surface portion 125a from a side close to the body portion 125b to a side close to the first capping layer 126. The intensity of Ge further decreases to zero in the first capping layer 126. The Ge-curve shows a germanium concentration of the PCM element 125 is larger than the first capping layer 126, and a germanium concentration of the surface portion 125a may be smaller than a germanium concentration of the body portion 125b.

In addition, since the surface portion 125a was nitrided the N-curve has a peak pk5 at the surface portion 125a of the PCM element 125, and this shows that a nitrogen concentration of the surface portion 125a of the PCM element 125 is larger than a nitrogen concentration of the first capping layer 126 and a nitrogen concentration of the body portion 125b of the PCM element 125. The intensity of nitrogen gradually decreases from the surface portion 125a to the first capping layer 126. In the first capping layer 126, the intensity of nitrogen is substantially maintained at a constant value, the intensity of nitrogen gradually increases as the first capping layer 126 gets closer to the surface portion 125a of the PCM element 125, and the intensity of nitrogen gradually decreases as the first capping layer 126 gets closer to its top surface 1261. On the other hand, the intensity of nitrogen gradually decreases from the surface portion 125a to the body portion 125b. The body portion 125b includes almost no nitrogen.

The O-curve has a peak pk6 near the top surface 1261 (with reference to FIG. 1A) of the first capping layer 126, and this may due to surface oxidation caused by exposure to the external environment when transferring the example stacking structure to the EDX line scan. The intensity of oxygen gradually decreases from the top surface 1261 of the first capping layer 126 to the bottom surface 1262 (with reference to FIG. 1A) of the first capping layer 126. In the first capping layer 126, it may include a small amount of oxygen due to impurities during the fabrication of the first capping layer 126. The intensity of oxygen gradually decreases from the surface portion 125a to the body portion 125b and the body portion 125b includes almost no oxygen. Besides, a small amount of oxygen may be included in the surface portion 125a and this may due to the oxides, which were not completely removed by the nitridation treatment, remaining on the PCM element 125.

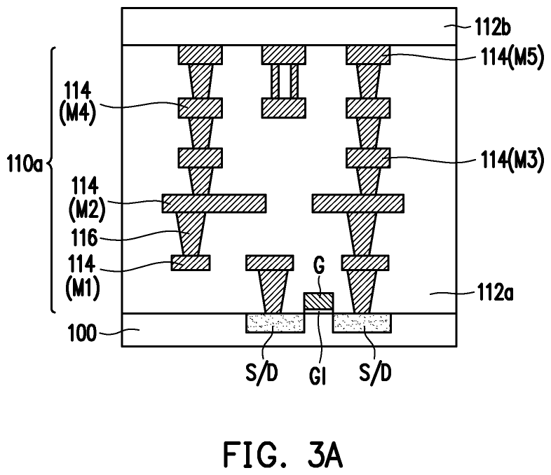

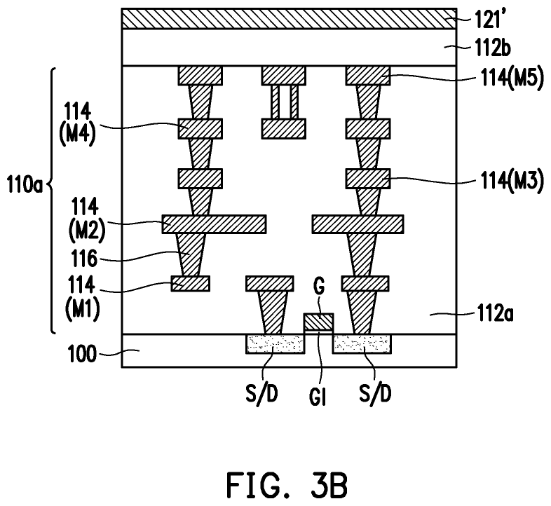

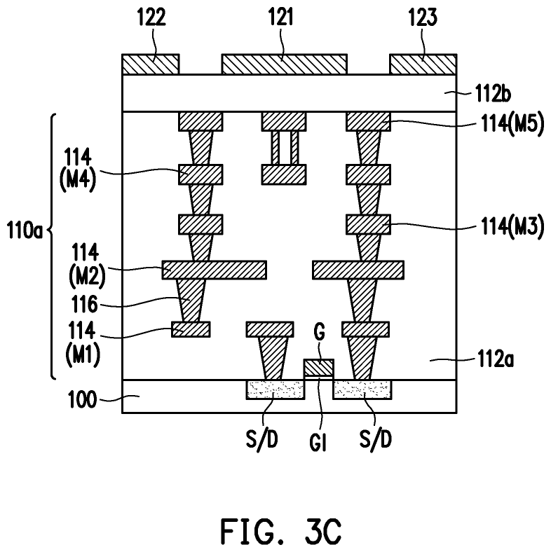

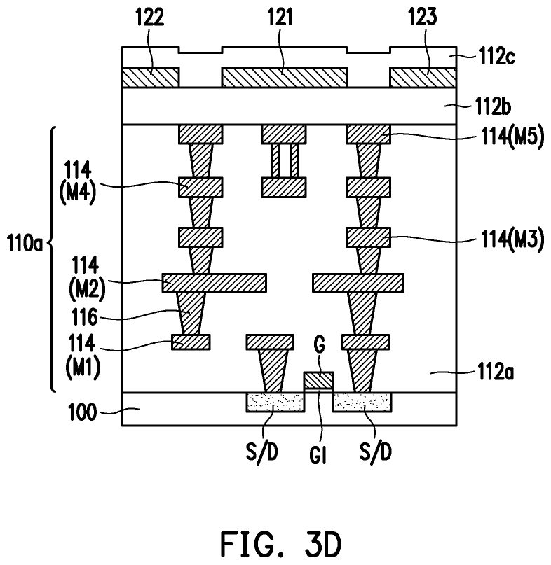

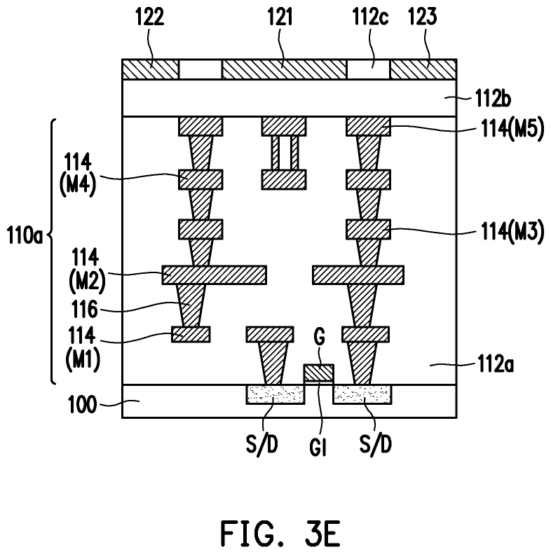

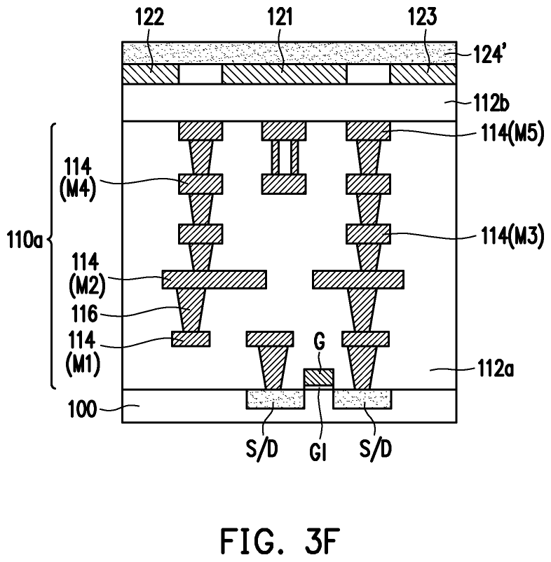

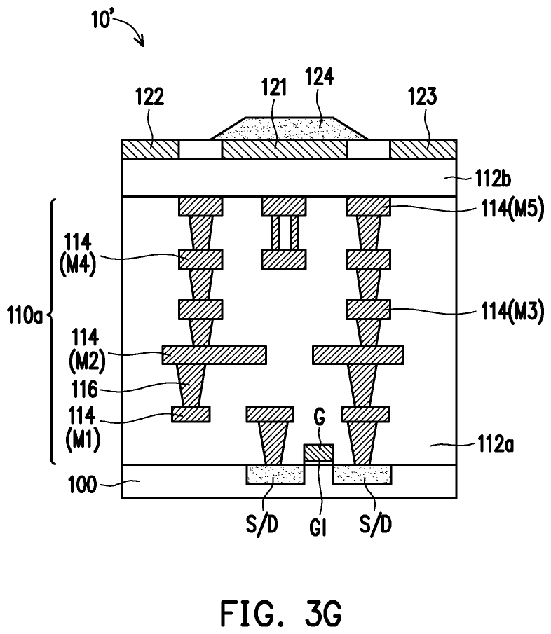

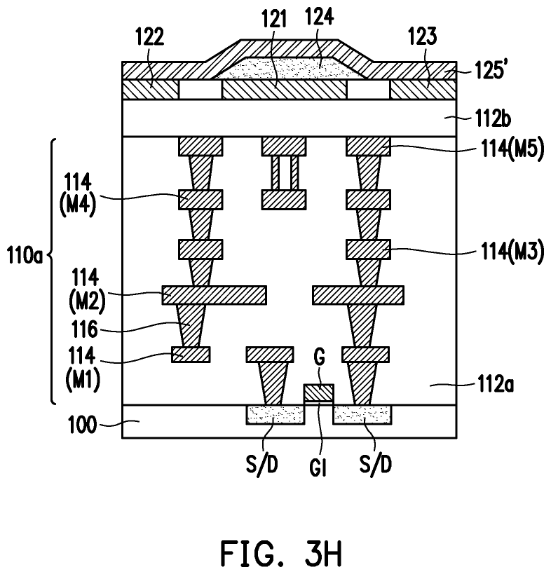

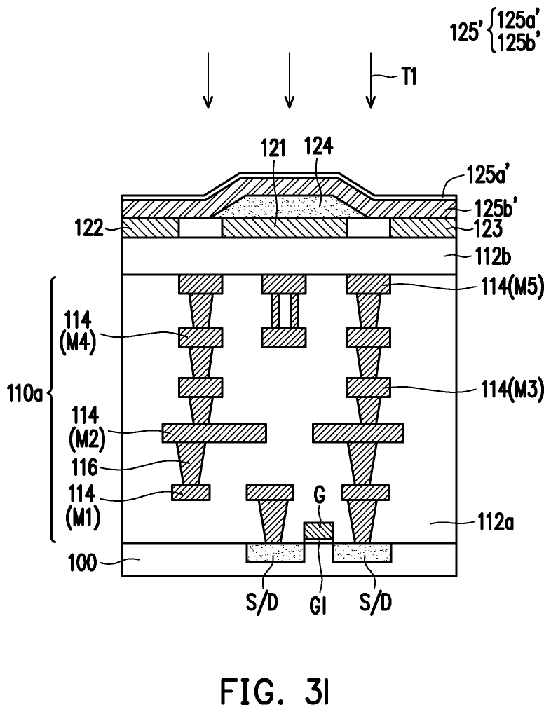

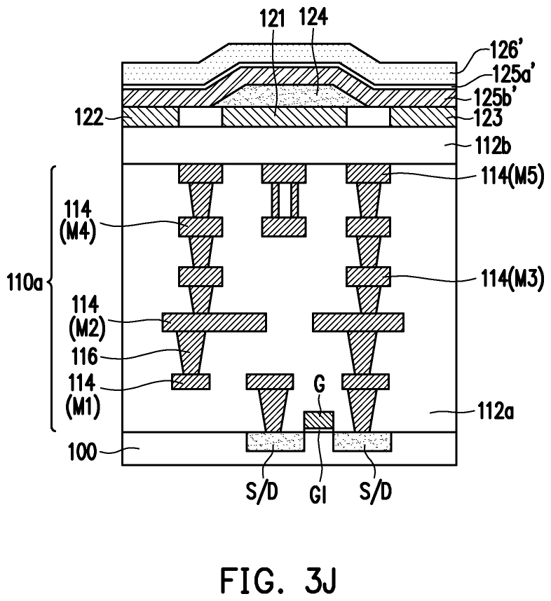

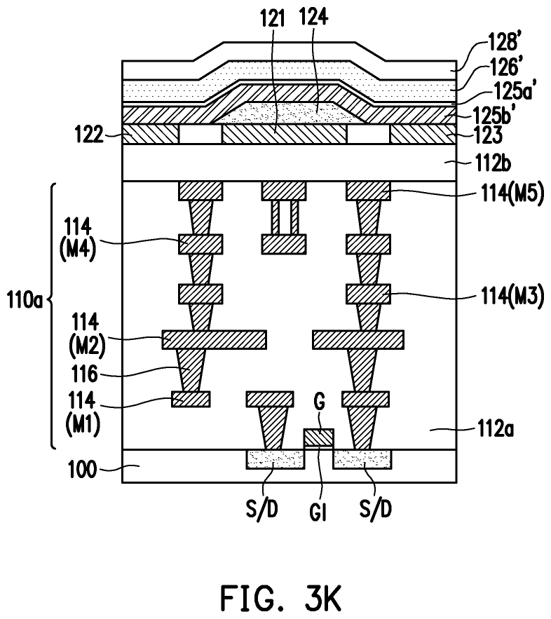

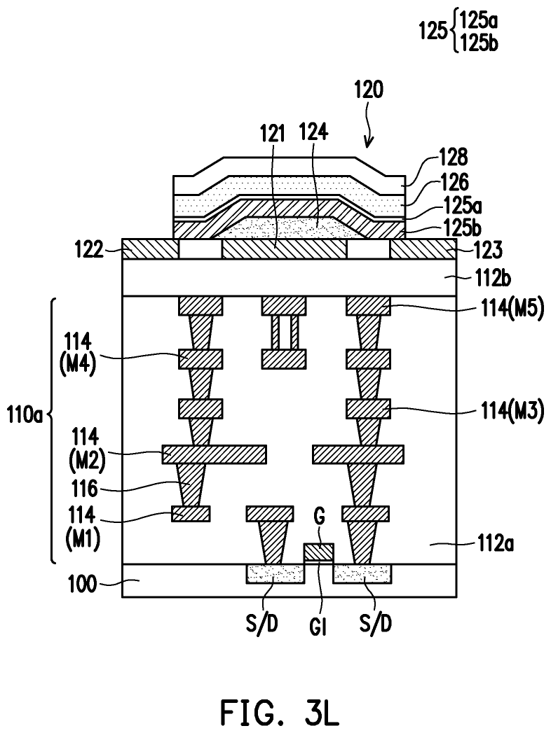

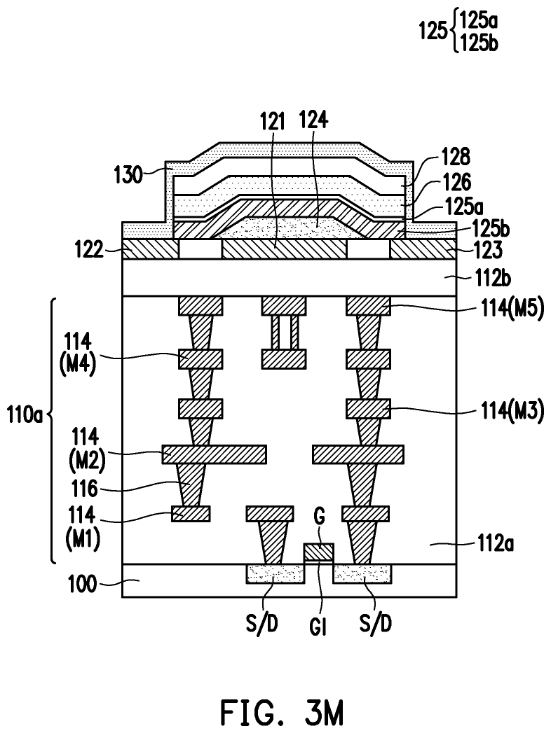

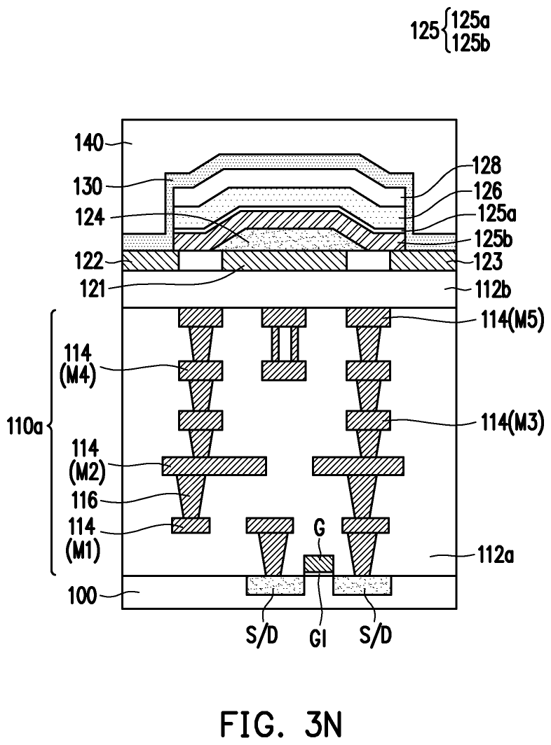

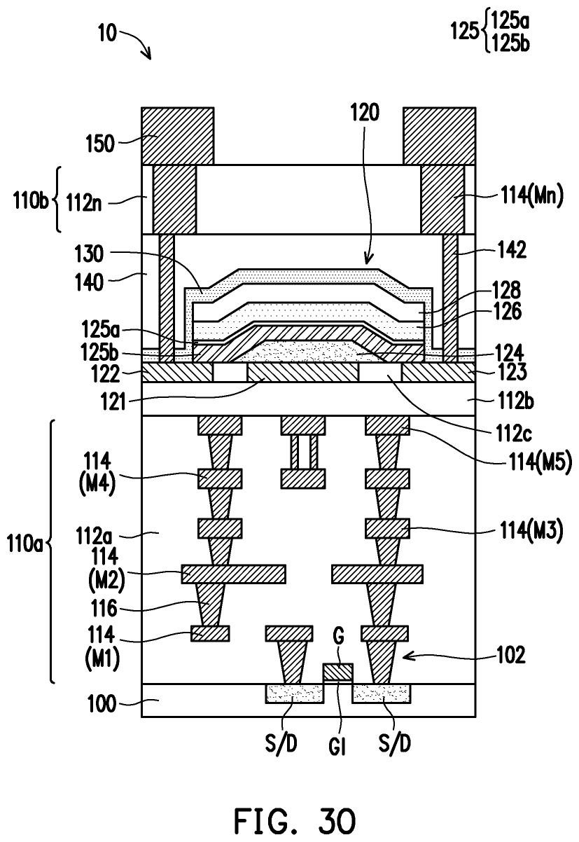

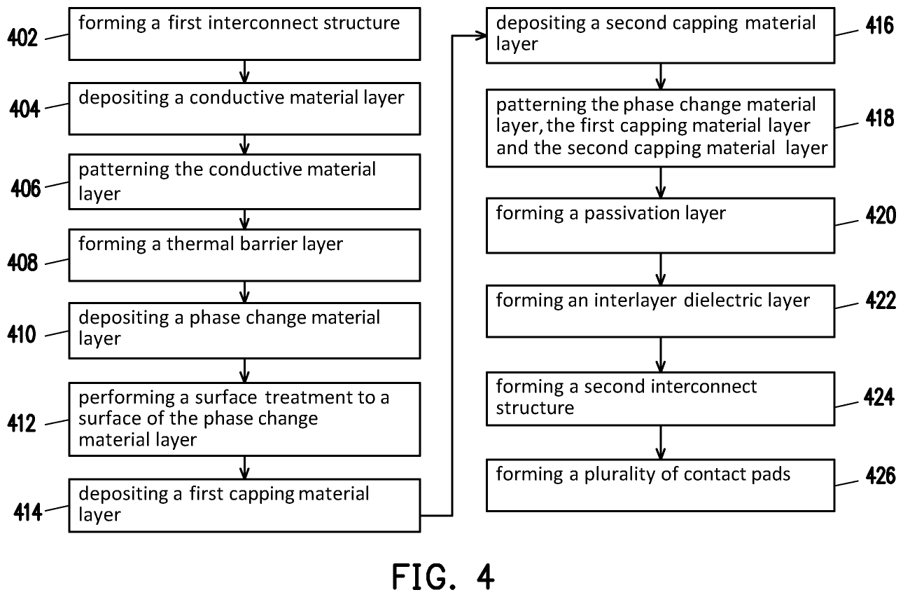

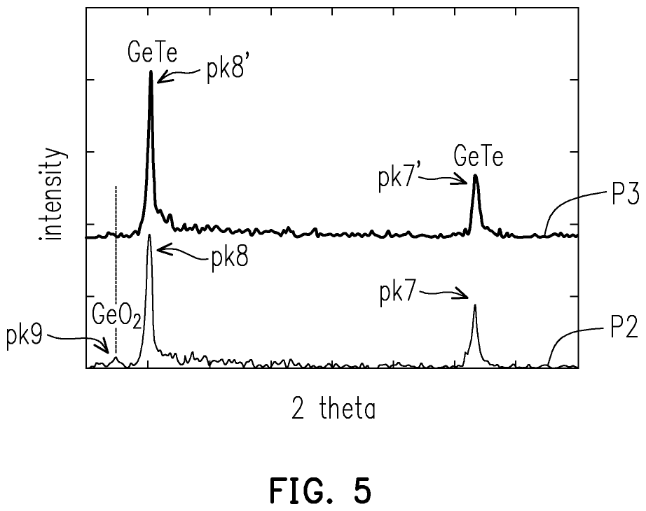

FIGS. 3A to 3O are schematic cross-sectional views illustrating structures formed at various stages of a method of forming a semiconductor device 10 according to some embodiments of the present disclosure. FIG. 4 is a flowchart illustrating operations of a method of forming the semiconductor device 10, according to some embodiments of the present disclosure. It should be noted herein that, in embodiment provided in FIGS. 3A to 3O, element numerals and partial content of the embodiments provided in FIG. 1 are followed, the same or similar reference numerals being used to represent the same or similar elements, and description of the same technical content being omitted. For a description of an omitted part, reference may be made to the foregoing embodiment, and the descriptions thereof are omitted herein. FIG. 5 is an X-ray diffraction (XRD) analysis result for an example of the surface of the phase change material layer 125′ before and after the nitridation treatment T1 according to some embodiments of the present disclosure.

Referring to FIGS. 3A and 4, in operation 402, a first interconnect structure 110a is formed on a substrate 100. Specifically, the substrate 100 is provided, and one or more active devices 102 may be formed on/over the substrate 100. In some embodiments, the substrate 100 may be a silicon (Si) substrate. In some other embodiments, the substrate 100 may include other semiconductors such as germanium (Ge), silicon germanium (SiGe), or a III-V semiconductor material. Example III-V semiconductor materials may include gallium arsenide (GaAs), indium phosphide (InP), gallium phosphide (GaP), gallium nitride (GaN), gallium arsenide phosphide (GaAsP), aluminum indium arsenide (AlInAs), aluminum gallium arsenide (AlGaAs), gallium indium phosphide (GaInP), and indium gallium arsenide (InGaAs). The substrate 100 may also include a buried insulating layer, such as a buried silicon oxide layer, to have a silicon-on-insulator (SOI) structure. In some embodiments, one or more active devices 102, such as metal-oxide-semiconductor field-effect transistors (MOSFETs), complementary metal-oxide-semiconductor (CMOS) transistors, fin field-effect transistors (FinFETs), gate-all-around field-effect transistors (GAA FETs) and etc., may be disposed on/over the substrate 100. A dielectric material layer may (not shown) be formed on the substrate 100 by, for example, chemical vapor deposition (CVD), physical vapor deposition (PVD), atomic layer deposition (ALD), thermal oxidation, some other deposition or growth process, or a combination of the foregoing. The dielectric material layer may be patterned via a lithography process, such as photolithography, extreme ultraviolet lithography, or the like to form a dielectric layer 112a. The dielectric layer 112a may have corresponding openings for subsequent connection purpose. Then, a conductive material (not shown) may be formed on the dielectric layer 112a and in the openings and then patterned to form a conductive layer 114 and a via 116. In some embodiments, the conductive material may be formed by, for example, CVD, PVD, ALD, sputtering, electrochemical plating, electroless plating, some other deposition process, or a combination of the foregoing. In some embodiments, a process for patterning the conductive material includes forming a mask layer (e.g., positive/negative photoresist, a hardmask, and etc.) on the metal material, and performing an etching process (e.g., wet etching process, dry etching process, reactive ion etching (RIE) process, etc.) to the conductive material to remove the unmasked portion of the conductive material, and stripping away the mask layer. The first interconnect structure 110a is formed by repeating the aforementioned process until the target number of the conductive layers 114 is reached. In some embodiments, the dielectric layer 112a may include a silicon oxide (e.g., SiO₂), a low-k dielectric (e.g., a dielectric material with a dielectric constant less than about 3.9), or the like. The conductive layer may be or include, for example, copper (Cu), gold (Au), silver (Ag), tungsten (W), or other suitable conductive material.

A dielectric layer 112b is formed on the first interconnect structure 110a to cover the topmost conductive layer 114 (i.e. the fifth conductive layer M5 in FIG. 3A) of the first interconnect structure 110a. A material of the dielectric layer 112b may be the same as the dielectric layer 112a. The dielectric layer 112b may be formed by, for example, chemical vapor deposition (CVD), physical vapor deposition (PVD), atomic layer deposition (ALD), thermal oxidation, some other deposition or growth process, or a combination of the foregoing. Please note that a boundary line between the dielectric layer 112b and the dielectric layer 112a is illustrated for interpretation purpose. Practically, the boundary line may not be observed.

Referring to FIGS. 3B and 4, in operation 404, a conductive material layer 121′ is formed on the dielectric layer 112b over the substrate 100. The conductive material layer 121′ may be formed by, for example, CVD, PVD, ALD, sputtering, electrochemical plating, electroless plating, some other deposition process, or a combination of the foregoing. The conductive material layer 121′ may be isolated from the topmost conductive layer 114 of the first interconnect structure 110a by the dielectric layer 112b. In some embodiments, conductive material layer 121′ includes a metal (e.g., tungsten (W), iridium (Ir), ruthenium (Ru), platinum (Pt), gold (Au), or the like), a metal nitride (e.g., TiN), some other conductive material, or a combination of the foregoing (e.g., a combination of tungsten (W) and TiN).

Referring to FIGS. 3C and 4, in operation 406, the conductive material layer 121′ is patterned to form a heating structure 121, a first conductive structure 122 and a second conductive structure 123. In some embodiments, a process for patterning the conductive material layer 121′ includes forming a mask layer (not shown) (e.g., positive/negative photoresist, a hardmask, and etc.) on the conductive material layer 121′, and performing an etching process (e.g., wet etching process, dry etching process, RIE process, etc.) to the conductive material layer 121′ to remove the unmasked portion of the conductive material layer 121′, and stripping away the mask layer.

Referring to FIG. 3D, a dielectric layer 112c is formed on the dielectric layer 112b, the heating structure 121, the first conductive structure 122 and the second conductive structure 123. The dielectric layer 112c may be formed by, for example, chemical vapor deposition (CVD), physical vapor deposition (PVD), atomic layer deposition (ALD), thermal oxidation, some other deposition or growth process, or a combination of the foregoing. In some embodiments, a material of the dielectric layer 112c may be the same as the dielectric layer 112b. Please note that a boundary line between the dielectric layer 112b and the dielectric layer 112c is illustrated for interpretation purpose. Practically, the boundary line may not be observed.

Then referring to FIG. 3E a planarization process (e.g., chemical-mechanical polishing (CMP), an etch back process, etc.) is performed to make a top surface of the dielectric layer 112c level with top surfaces of the heating structure 121, the first conductive structure 122 and the second conductive structure 123. The heating structure 121 is electrically isolated from the first conductive structure 122 and the second conductive structure 123 by the dielectric layer 112c.

Referring to FIGS. 3F-3G and 4, in operation 408, a thermal barrier layer 124 is formed on the heating structure 121. For example, in FIG. 3F, a thermal barrier material layer 124′ is formed on the heating structure 121, the first conductive structure 122, the second conductive structure 123 and the dielectric layer 112c. The thermal barrier material layer 124′ may be formed by, for example, chemical vapor deposition (CVD), physical vapor deposition (PVD), atomic layer deposition (ALD), thermal oxidation, some other deposition or growth process, or a combination of the foregoing. Then, In FIG. 3G, the thermal barrier material layer 124′ is patterned via a lithography process, such as photolithography, extreme ultraviolet lithography, or the like to form a thermal barrier layer 124. In some embodiments, the thermal barrier layer 124 may be or include, for example, a silicon nitride (SiN), a silicon carbide (SiC), a silicon carbonitride (SiCN), a metal nitride (e.g., aluminum nitride (AlN)), carbon (C), some other thermal barrier material, or a combination of the foregoing.

Referring to FIGS. 3H and 4, in operation 410, a phase change material layer 125′ is formed on the thermal barrier layer 124, the first conductive structure 122 and the second conductive structure 123. The phase change material layer 125′ may be formed by, for example, chemical vapor deposition (CVD), physical vapor deposition (PVD), atomic layer deposition (ALD), some other deposition process, or a combination of the foregoing. In some embodiments, a surface of the phase change material layer 125′ may formed metal oxides (such as GeO₂, GeO and the like) due to vacuum-break after the completion of the deposition of the phase change material layer 125′. In some embodiments, the phase change material layer 125′ may include germanium telluride (GeTe), germanium antimony telluride (GeSbTe), other suitable materials capable of changing resistive states by changing phases or a combination of the foregoing.

Referring to FIGS. 3I and 4, in operation 412, a surface treatment T1 is performed on a surface of the phase change material layer 125′. For example, a nitridation treatment is performed on a surface of the phase change material layer 125′ to make a chemical composition of a surface portion 125a′ of the phase change material layer 125′ different from a chemical composition of the body portion 125b′ of the phase change material layer 125′. In some embodiments, the nitridation treatment T1 includes exposing the surface of the phase change material layer 125′ to a nitrogen plasma. During the nitridation treatment, the ionized nitrogen may react with the surface of the phase change material layer 125′ to bond nitrogen atoms to the surface of the phase change material layer 125′ and thus Ge—N bonds may form on the surface of the phase change material layer 125′. On the other hand, a volatile GeO may escape from the surface of the phase change material layer 125′ during nitridation treatment T1 and thereby significantly reducing the amount of oxides formed on the surface of the phase change material layer 125′. In some embodiments, the nitridation treatment T1 is performed under 100 degrees Celsius to 400 degrees Celsius for less than 5 minutes. In some embodiments, a carrier gas (such as argon or other suitable noble gas) may be used with the nitrogen plasma.

An XRD analysis is performed to an example of the surface of the phase change material layer 125′ before and after the nitridation treatment T1 and the result is shown in FIG. 5, As shown in FIG. 5, the XRD pattern P2 is the result obtained before nitridation treatment T1 to the surface of the phase change material layer 125′. The XRD pattern P2 has two peaks pk7 and pk8 corresponding to the characteristic peaks of GeTe, and a peak pk9 corresponding to the characteristic peak of GeO₂. This shows that the surface of the phase change material layer 125′ including GeTe may be oxidized to form germanium oxides before nitridation treatment T1. The oxides was formed due to vacuum-break after the completion of the deposition of the phase change material layer 125′.

As shown in FIG. 5, the XRD pattern P3 is the result obtained after nitridation treatment T1 to the surface of the phase change material layer 125′. The XRD pattern P3 still has two peaks pk7′ and pk8′ corresponding to the characteristic peaks of GeTe, but the signal corresponding to the characteristic peak of GeO₂ significantly reduces compared with the peak pk9 shown in the XRD pattern P2. In FIG. 5, the XRD pattern P3 has little or nearly no signal corresponding to the characteristic peak of GeO₂. This shows that the nitridation treatment T1 to the surface of phase change material layer 125′ can effectively reduce the oxides formed on the surface of the phase change material layer 125′ and thereby reducing the resistivity of the phase change material layer 125′ and improving the switch performance.

Referring to FIGS. 3J and 4, in operation 414, a first capping material layer 126′ is formed on the phase change material layer 125′ by, for example, chemical vapor deposition (CVD), physical vapor deposition (PVD), atomic layer deposition (ALD), thermal oxidation, some other deposition or growth process, or a combination of the foregoing. In some embodiments, the first capping material layer 126′ includes silicon nitride, silicon carbide, silicon carbonitride, or other suitable insulating materials. Referring to FIGS. 3K and 4, in operation 416, a second capping material layer 128′ is formed on the first capping material layer 126′ by, for example, chemical vapor deposition (CVD), physical vapor deposition (PVD), atomic layer deposition (ALD), thermal oxidation, some other deposition or growth process, or a combination of the foregoing. In some embodiments, the second capping material layer 128′ includes a silicon oxide (e.g., SiO₂), a silicon nitride (e.g., SiN), a silicon oxynitride (e.g., SiON), some other insulating material, or a combination of the foregoing.

Referring to FIGS. 3L and 4, in operation 416, the phase change material layer 125′, the first capping material layer 126′ and the second capping material layer 128′ are patterned to form a PCM element 125, a first capping layer 126 and a second capping layer 128. Specifically, a patterned mask layer (not shown) is formed on the second capping material layer 128′. With the patterned mask layer in place, an etching process is performed on the second capping material layer 128′ to form a second capping layer 128, and then the patterned mask layer is removed. The second capping layer 128 may be used as a hard mask to pattern the first capping material layer 126′ by an etching process to form a first capping layer 126. The first capping layer 126 and the second capping layer 128 may be used as hard masks to pattern the phase change material layer 125′ by an etching process to form a PCM element 125. In some embodiments, the etching process may be, for example, a wet etching process, a dry etching process, a reactive ion etching (RIE) process, some other etching process, or a combination of the foregoing. In this way, a PCM switch 120 including the PCM element 125, the heating structure 121, the first conductive structure 122, the second conductive structure 123 is formed.

In some embodiments, during the etching process for the phase change material layer 125′, the second capping layer 128 may be partially removed. In other embodiments, during the etching process for the phase change material layer 125′, the second capping layer 128 may be totally removed.

Referring to FIGS. 3M and 4, in operation 420, a passivation layer 130 is formed over the first conductive structure 122, the second conductive structure 123 and the second capping layer 128 by, for example, chemical vapor deposition (CVD), physical vapor deposition (PVD), atomic layer deposition (ALD), thermal oxidation, some other deposition or growth process, or a combination of the foregoing. In some embodiments, the passivation layer 130 is conformally formed on the PCM switch 120. In some embodiments, the passivation layer 130 may directly cover a top surface of the first conductive structure 121, a top surface of the second conductive structure 123, sidewalls of the PCM element 125, sidewalls of the first capping layer 126, and a top surface and sidewalls of the second capping layer 128. In other embodiments, the passivation layer 130 may directly contact a top surface of the first capping layer 126 when the second capping layer 128 is totally removed during the etching process. In some embodiments, a material of the passivation layer 130 includes silicon nitride, silicon carbide, silicon carbonitride, or other suitable insulating materials.

Referring to FIGS. 3N and 4, in operation 422, an interlayer dielectric (ILD) layer 140 is formed on the passivation layer 130. The ILD layer 140 may be formed by, for example, chemical vapor deposition (CVD), physical vapor deposition (PVD), atomic layer deposition (ALD), some other deposition process, or a combination of the foregoing. In some embodiments, the ILD layer 140 may include a silicon oxide (e.g., SiO₂), a low-k dielectric (e.g., a dielectric material with a dielectric constant less than about 3.9), or the like.

Referring to FIGS. 3O and 4, in operation 424, a second interconnect structure 110b is formed on the ILD layer 140. For example, an nth conductive layer Mn is formed on the ILD layer 140 and a via 142 is formed in the ILD layer 140 to connect between the nth conductive layer Mn and the first conductive structure 122 or the second conductive structure 123. Specifically, an opening (not shown) may be formed in the ILD layer 140 to expose the surface of the first conductive structure 122 or the second conductive structure 123. The opening may be formed by a lithography process (eg. photolithography, extreme ultraviolet lithography, or the like) and/or an etching process (eg. wet etching process, dry etching process or the like). Then, a metal material (not shown) may be formed on the ILD layer 140 and fill in the opening and then patterned to form the nth conductive layer Mn on the ILD layer 140 and the via 142 in the opening, which is similar to the formation process of the conductive layer 114 of the first interconnect structure 110a. In some embodiments, the nth conductive layer Mn may be or include, for example, copper (Cu), gold (Au), silver (Ag), tungsten (W), or other suitable conductive material.

Subsequently, a dielectric layer 112n may be formed on the ILD layer 140 and laterally cover the nth conductive layer Mn. The dielectric layer 112n may be formed by, for example, chemical vapor deposition (CVD), physical vapor deposition (PVD), atomic layer deposition (ALD), thermal oxidation, some other deposition or growth process, or a combination of the foregoing. In some embodiments, the dielectric layer 112n may include one or more stacked dielectric layers, which may respectively include a silicon oxide (e.g., SiO₂), a low-k dielectric (e.g., a dielectric material with a dielectric constant less than about 3.9), or the like. In some embodiments, the dielectric layer 112n may deposit to cover the surface of the nth conductive layer Mn and then a planarization process (e.g., chemical-mechanical polishing (CMP), an etch back process, etc.) is performed to make the surface of the dielectric layer 112n level with the surface of the nth conductive layer Mn.

The dielectric layer 112n and the nth conductive layer Mn may be regarded as a second interconnect structure 110b. Please note that FIG. 3O shows that the second interconnect structure 110b contains one dielectric layer and one conductive layer formed on the ILD layer, but it is not limited thereto. The second interconnect structure 110b may contain one or more dielectric layers and one or more conductive layers depending on the circuit design. The second interconnect structure 110b may also include vias to vertically connected between adjacent conductive layers. The manufacturing process of the second interconnect structure 110b may be similar to the manufacturing process of the first interconnect structure 110a.

In some embodiments, the first interconnect structure 110a, the second interconnect structure 110b, the dielectric layers 112b, 112c and the ILD layer 140 may be collectively referred to the interconnect structure 110 (shown in FIG. 1). The dielectric layers 112a, 112b, 112c, 112n and the ILD layer 140 may be regarded as a dielectric structure 112, so the conductive layers 114 and the PCM switch 120 are formed in the dielectric structure 112.

Referring to FIGS. 3O and 4, in operation 426, a plurality of contact pads 150 are formed on the second interconnect structure 110b. In some embodiments, the contact pads 150 may be formed on the corresponding conductive layer 114 to electrically connect with the first conductive structure 122 or the second conductive structure 123. The contact pads may be formed by the process similar to the formation of the conductive layers 114. In some embodiments, the contact pads 150 may be or include, for example, copper (Cu), gold (Au), silver (Ag), tungsten (W), aluminum (Al), Titanium (Ti), an alloy or a combination thereof, or other suitable conductive material.

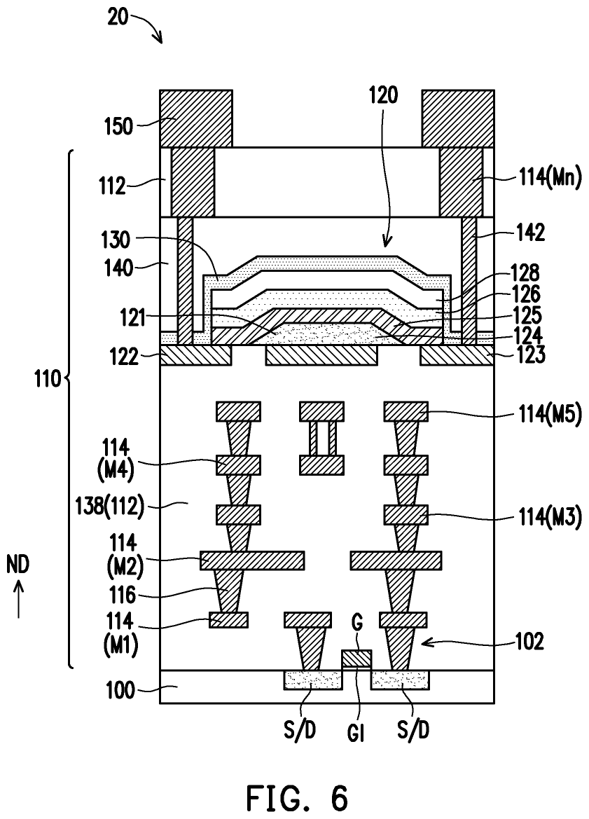

FIG. 6 is a schematic cross-sectional view of a semiconductor device 20 according to some embodiments of the present disclosure. It should be noted herein that, in embodiment provided in FIG. 6 element numerals and partial content of the embodiments provided in FIG. 1 are followed, the same or similar reference numerals being used to represent the same or similar elements, and description of the same technical content being omitted. For a description of an omitted part, reference may be made to the foregoing embodiment, and the descriptions thereof are omitted herein.

Referring to FIG. 6, the difference between the present embodiment to the embodiment of FIG. 1 is that the chemical composition in the surface portion of the PCM element 125 is the same as the chemical composition in the body portion of the PCM element 125. That is, the PCM element 125 has a uniform chemical composition. In the present embodiment, the PCM element 125 and the first capping layer 126 are formed in-situ, and therefore the oxides (such as GeO, GeO₂ or the like) may not form at the interface between the PCM element 125 and the first capping layer 126, since no vacuum-break occurs when transferring the formation process of the PCM element 125 to the formation process of the first capping layer 126. Accordingly, an oxygen concentration at the interface between the PCM element 125 and the first capping layer 126 is less than an oxygen concentration in the first capping layer 126. In some embodiments, the surface of the PCM element 125 is substantially oxide-free. The surface of the PCM element 125 is not surface-treated, and thus there is no nitrogen-containing layer (referred to FIG. 1) formed at the surface portion of the PCM element 125.

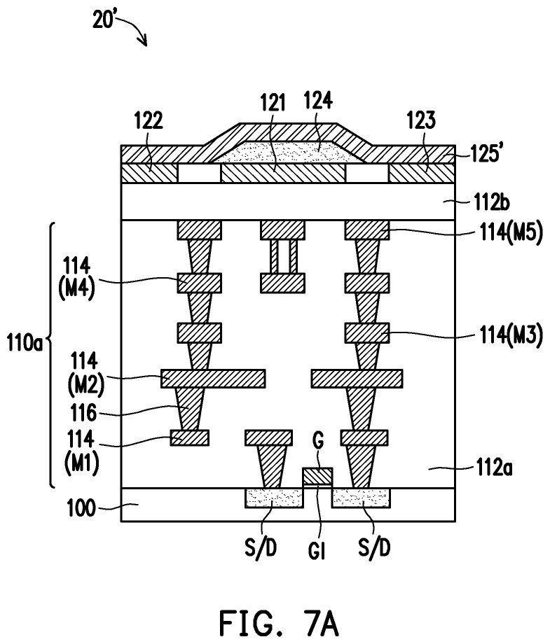

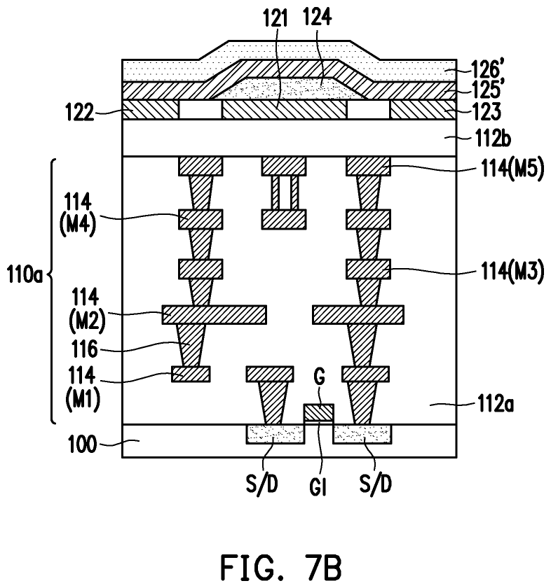

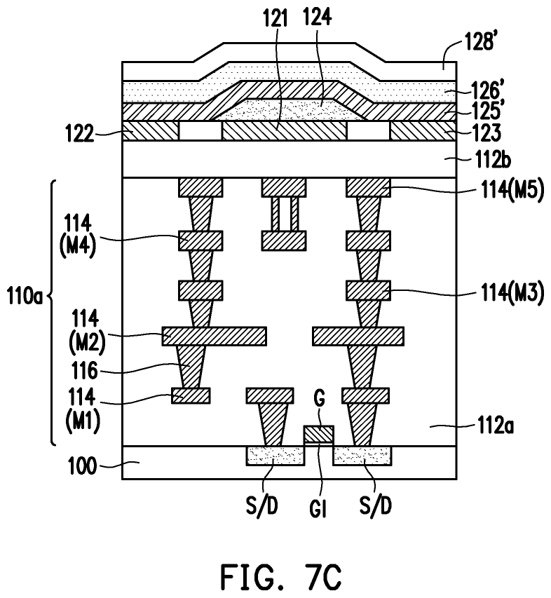

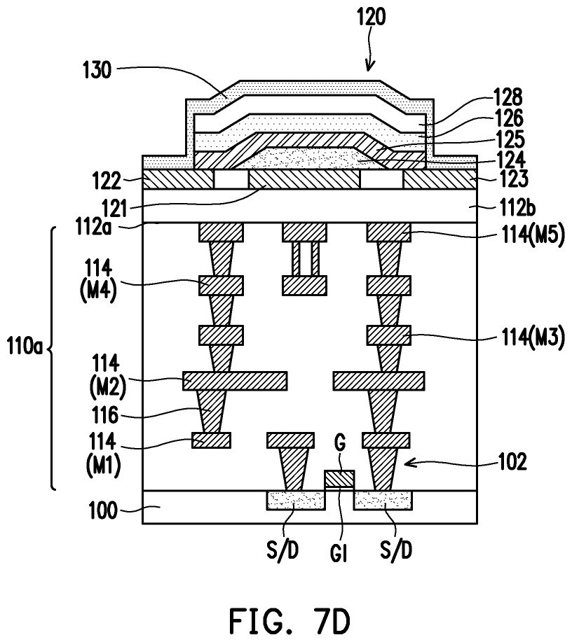

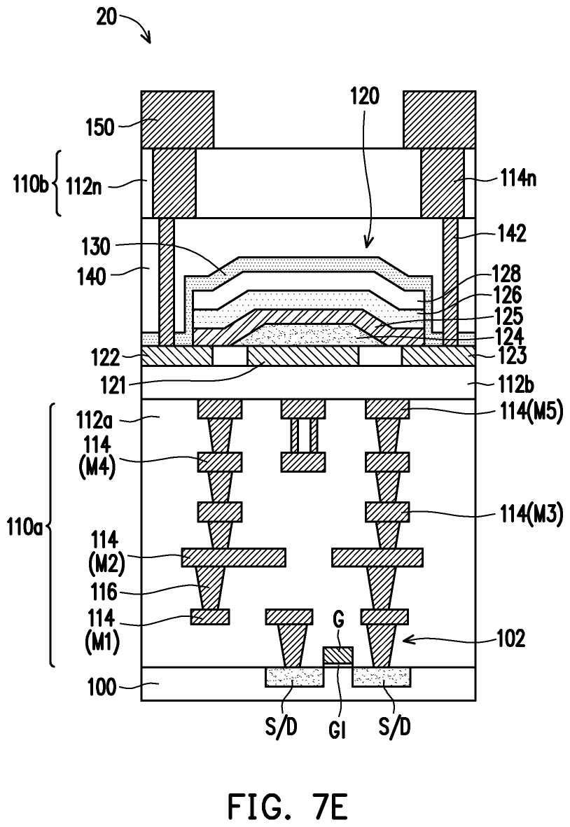

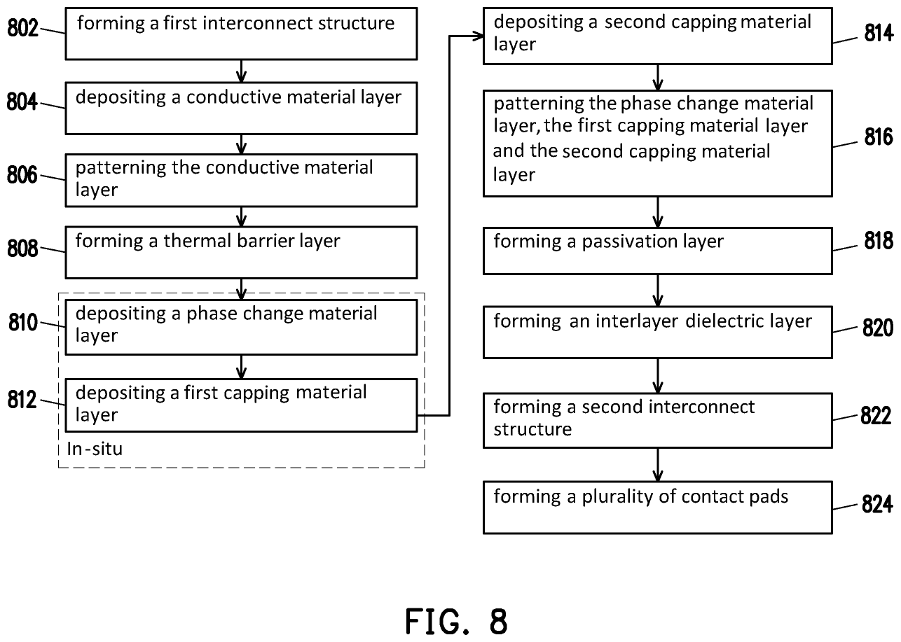

FIGS. 7A to 7E are schematic cross-sectional views illustrating structures formed at various stages of a method of forming a semiconductor device 20 according to some embodiments of the present disclosure. FIG. 8 is a flowchart illustrating operations of a method of forming the semiconductor device 20, according to some embodiments of the present disclosure. FIGS. 7A to 7E may be a process continued from FIG. 3G, and thus the formation of the first interconnect structure 110a, the dielectric layers 112b and 112c, the heating structure 121, the first conductive layer 122, the second conductive layer 123 and the thermal barrier layer 124 may refer to the process shown in FIGS. 3A to 3G.

Referring to FIGS. 7A, 7B and 8, a workpiece 20′ including a first interconnect structure 110a, a heating structure 121, a first conductive structure 122, a second conductive structure 123 and a thermal barrier layer 124 is provided. The workpiece 20′ is similar to the workpiece 10′ shown in FIG. 3G. The method of forming the workpiece 20′ includes operations 802 to 808, which is similar to the operations 402 to 408 for forming the workpiece 10′. In operation 810, a phase change material layer 125′ is formed on the thermal barrier layer 124, the first conductive structure 122 and the second conductive structure 123. In operation 812, a first capping material layer 126′ is formed on the phase change material layer 125′. The step of forming the first capping material layer 126′ (operation 812) is in-situ performed with the step of forming the phase change material layer 125′ (operation 810). In some embodiments, the workpiece 20′ is placed in a deposition tool. The deposition tool may include a first chamber for a first deposition process and a second chamber for a second deposition process. In some embodiments, the workpiece 20′ may transfer between the first chamber and the second chamber by a transfer chamber. During the transferring, the first chamber, the second chamber and the transfer chamber are kept vacuumed. Therefore, the workpiece 20′ may be first placed in a first chamber to deposit the phase change material layer 125′. After the formation of the phase change material layer 125′, the workpiece 20′ is transferred from the first chamber to the second chamber through the transfer chamber. Since the first chamber, the second chamber and the transfer chamber are kept vacuumed, the workpiece 20′ is not exposed to the external environment and thereby oxides may not form on the surface of the phase change material layer 125′ during the transferring. Then, the first capping material layer 126′ may deposit on the phase change material layer 125′ in the second chamber. In this way, the phase change material layer 125′ and the first capping material layer 126′ may be formed in-situ. However, it is not limited thereto. Other processes suitable for in-situ forming of the phase change material layer 125′ and the first capping material layer 126′ may also be used. For example, the deposition tool may include one chamber, and the workpiece 20′ may be placed in the chamber to first deposit the phase change material layer 125′. After the formation of the phase change material layer 125′, the process gases in the chamber may be evacuated, and the noble gas may be purged into the chamber and then evacuated for several times to remove the reactive gas in the chamber. Then, the first capping material layer 126′ may deposit on the phase change material layer 125′ by transporting corresponding reactive gases into the chamber.

In some embodiments, the phase change material layer 125′ and the first capping material layer 126′ may be formed by similar deposition method, such as chemical vapor deposition (CVD), physical vapor deposition (PVD), atomic layer deposition (ALD) or some other deposition methods.

Referring to FIGS. 7C and 8, in operation 814, a second capping material layer 128′ is formed on the first capping material layer 126′, similar to the process described in FIG. 3K.

Referring to FIGS. 7D and 8, in operation 816, the phase change material layer 125′, the first capping material layer 126′ and the second capping material layer 128′ are patterned to form a PCM element 125, a first capping layer 126 and a second capping layer 128, similar to the process described in FIG. 3L. Then, in operation 818, a passivation layer 130 is formed on the PCM switch 120, similar to the process described in FIG. 3M.

Referring to FIGS. 7E and 8, in operation 820, an ILD layer 140 is formed on the passivation layer 130, similar to the process described in FIG. 3N. In operation 822, a second interconnect structure 110b is formed on the ILD layer 140, similar to the process described in FIG. 3O. In operation 824, a plurality of contact pads 150 are formed on the second interconnect structure 110b, similar to the process described in FIG. 3O.

In some embodiments, since a surface treatment is performed on a phase change material layer, so that oxides formed on the surface of the phase change material layer may be reduced and thereby reducing the resistivity R_{ON} of the PCM switch in the “ON” state and further improving the switch performance. In other embodiments, since a phase change material layer and a capping layer are formed in-situ, so that an oxide may not formed on the surface of the phase change material layer and thereby reducing the resistivity R_{ON} of the PCM switch in the “ON” state and improving the switch performance.

According to some embodiments of the present disclosure, a semiconductor device is provided. The semiconductor device includes a phase change material element over a substrate, a first conductive structure, a second conductive structure, a heating structure and a first capping layer. The phase change material element includes a body portion and a surface portion on a top surface of the body portion. A nitrogen concentration of the surface portion is larger than a nitrogen concentration of the body portion. The first conductive structure is physically and electrically connected to the phase change material element. The second conductive structure is physically and electrically connected to the phase change material element. The first conductive structure and the second conductive structure are laterally spaced apart. The heating structure is configured to heat the phase change material structure. The first capping layer is disposed on the surface of the phase change material element.

According to some embodiments of the present disclosure, a semiconductor device is provided. The semiconductor device includes a phase change material switch. The phase change material switch includes a phase change material structure, a nitrogen-containing layer, a first conductive structure and a second conductive structure. The nitrogen-containing layer is disposed on the phase change material structure. The first conductive structure physically and electrically connected to a first end of the phase change material structure. The second conductive structure physically and electrically connected to a second end of the phase change material structure opposite to the first end of the phase change material structure.

According to some embodiments of the present disclosure, a method of forming a semiconductor device is provided. The method includes the following steps. A conductive material layer is deposited over a substrate. The conductive material layer is patterned to form a heating structure, a first conductive structure and a second conductive structure. The heating structure is disposed between the first conductive structure and the second conductive structure. A phase change material layer is deposited over the heating structure, the first conductive structure and the second conductive structure. A surface treatment is performed on a surface of the phase change material layer to remove an oxide layer on the phase change material layer. A capping material layer is deposited on the phase change material layer.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A semiconductor device, comprising:
a phase change material element over a substrate, wherein the phase change material element comprises:
a body portion; and
a surface portion on a top surface of the body portion, wherein a nitrogen concentration of the surface portion is larger than a nitrogen concentration of the body portion;
a first conductive structure physically and electrically connected to the phase change material element;
a second conductive structure physically and electrically connected to the phase change material element, wherein the first conductive structure and the second conductive structure are laterally spaced apart;
a heating structure configured to heat the phase change material element; and
a first capping layer disposed on a top surface of the phase change material element.

2. The semiconductor device according to claim 1, wherein the nitrogen concentration of the surface portion of the phase change material element is larger than a nitrogen concentration of the first capping layer.

3. The semiconductor device according to claim 1, wherein the body portion and the surface portion of the phase change material element comprise a germanium-containing chalcogenide.

4. The semiconductor device according to claim 3, wherein the surface portion of the phase change material element comprises Ge—N bonds.

5. The semiconductor device according to claim 1, further comprising:
a passivation layer disposed over the first capping layer and covering sidewalls of the phase change material element and a top surface and sidewalls of the first capping layer.

6. The semiconductor device according to claim 1, further comprising:
a second capping layer disposed between the first capping layer and the passivation layer, wherein a material of the second capping layer is different from a material of the first capping layer.

7. A semiconductor device, comprising:
a phase change material switch comprising:
a phase change material structure;
a nitrogen-containing layer disposed on the phase change material structure;
a first conductive structure physically and electrically connected to a first end of the phase change material structure; and
a second conductive structure physically and electrically connected to a second end of the phase change material structure opposite to the first end of the phase change material structure.

8. The semiconductor device according to claim 7, wherein the nitrogen-containing layer comprises germanium-containing chalcogenide, nitrogen and oxygen.

9. The semiconductor device according to claim 8, wherein an amount of nitrogen in the nitrogen-containing layer is larger than an amount of oxygen in the nitrogen-containing layer.

10. The semiconductor device according to claim 7, wherein the phase change material switch further comprising:
a capping layer disposed on the nitrogen-containing layer, wherein a nitrogen concentration of the nitrogen-containing layer is larger than a nitrogen concentration of the capping layer.

11. The semiconductor device according to claim 10, wherein a ratio of the nitrogen concentration of the nitrogen-containing layer to the nitrogen concentration of the capping layer is larger than 1.1.

12. The semiconductor device according to claim 10, wherein a material of the capping layer comprises silicon nitride, silicon carbide or silicon carbonitride.

13. The semiconductor device according to claim 7, wherein the nitrogen-containing layer is bonded to the phase change material structure by Ge—N bonds or Ge—Te bonds.

14. The semiconductor device according to claim 7, wherein a ratio of a thickness of the nitrogen-containing layer to a thickness of the phase change material layer is between 0.005 and 0.1.

15. The semiconductor device according to claim 7, wherein a thickness of the nitrogen-containing layer is between 10 angstroms and 50 angstroms.

16. A method of forming a semiconductor device, comprising:
depositing a conductive material layer over a substrate;
patterning the conductive material layer to form a heating structure, a first conductive structure and a second conductive structure, wherein the heating structure is disposed between the first conductive structure and the second conductive structure;
depositing a phase change material layer over the heating structure, the first conductive structure and the second conductive structure;
performing a surface treatment on a surface of the phase change material layer to remove an oxide layer on the phase change material layer; and
depositing a capping material layer on the phase change material layer.

17. The method according to claim 16, wherein the surface treatment comprises a nitridation treatment.

18. The method according to claim 17, wherein the nitridation treatment comprises exposing the surface of the phase change material layer to a nitrogen plasma to form a nitrogen-containing layer on the phase change material layer.

19. The method according to claim 18, wherein a nitrogen concentration of the nitrogen-containing layer is larger than a nitrogen concentration of the capping material layer.

20. The method according to claim 16, wherein after performing the surface treatment, Ge—N bonds are formed on the surface of the phase change material layer.
